(19) United States
(12) Patent Application Publication
(10) Pub. No.: US 2013/0141716 A1
(43) Pub. Date: Jun. 6, 2013

(54) PIEZOELECTRIC MOTOR, DRIVING DEVICE, ELECTRONIC COMPONENT CONVEYING DEVICE, ELECTRONIC COMPONENT INSPECTION DEVICE, PRINTING DEVICE, ROBOT HAND, AND ROBOT

(71) Applicant: Seiko Epson Corporation, Tokyo (JP)

(72) Inventor: Nobuyuki MIZUSHIMA, Shiojiri (JP)

(73) Assignee: SEIKO EPSON CORPORATION, Tokyo (JP)

(21) Appl. No.: 13/693,550

(22) Filed: Dec. 4, 2012

(30) Foreign Application Priority Data
Dec. 6, 2011 (JP) 2011-266552

(51) Int. Cl. H01L 41/053; G01N 21/13

(52) U.S. Cl. CPC H01L 41/053; G01N 21/13; Y10S 901/32
USPC 356/244; 310/348; 901/32

(57) ABSTRACT

A piezoelectric motor includes a piezoelectric element, electrodes provided in the piezoelectric element, electric wires connected to the electrodes, bond portions which bond the electrodes and the electrical wires, a storage case which stores the piezoelectric element, and support portions which are provided between the piezoelectric element and the storage case, wherein the bond portion and the electric wires are provided in the gap between the electrodes and the storage case.

### BACKGROUND

1. Technical Field

The present invention relates to a piezoelectric motor, a driving device, an electronic component conveying device, an electronic component inspection device, a printing device, a robot hand, and a robot.

2. Related Art

A piezoelectric motor which vibrates a vibrating body formed of a piezoelectric material to drive an object has been known. The piezoelectric motor can be of small size compared to an electromagnetic motor which rotates a rotor by means of an electromagnetic force, can obtain a large driving force, and can align the object with high resolution. For this reason, the piezoelectric motor is used as an actuator for various devices, such as a driving mechanism of a camera.

The piezoelectric motor operates under the following principle. First, a vibrating body (piezoelectric material) is formed to substantially have a rectangular parallelepiped shape, and has a convex portion in an end surface in a longitudinal direction. If a voltage with a predetermined frequency is applied to the vibrating body, vibration in which the vibrating body is stretched and vibration in which the vibrating body is bent are generated simultaneously. When this happens, the end surface of the vibrating body starts an elliptical motion to rotate in one direction. Accordingly, if the convex portion provided in the end surface is pressed against the object, the object can be moved in a given direction with a frictional force acting between the convex portion and the object.

Under this operation principle, it is necessary that the piezoelectric motor is used in a state where the convex portion provided in the end surface of the vibrating body is pressed against the object. It is also necessary to retain the vibrating body such that the vibrating body does not escape due to a reaction force received by the convex portion from the object when driving the object. Nevertheless, the vibration of the vibrating body should be permitted such that the convex portion performs an elliptical motion. Accordingly, a technique in which the vibrating body is fit in a storage case in a state where the convex portion protrudes, both sides of the vibrating body are supported from a bending direction through elastic members in the storage case, and the storage case is pressed against the object along with the vibrating body has been suggested (JP-A-11-346486).

However, the suggested technique has a problem that it is difficult to efficiently use mechanical energy generated by the vibrating body so as to drive the object. This is because both sides of the vibrating body are supported from the bending direction, such that the vibration of the vibrating body is easily transmitted to the outside through the storage case, and the vibration transmitted to the outside cannot be used for driving the object.

### SUMMARY

An advantage of some aspects of the invention is that it provides a piezoelectric motor capable of efficiently driving an object.

An aspect of the invention is directed to a piezoelectric motor which applies a voltage to a vibrating body containing a piezoelectric material to generate bending vibration, and brings a convex portion in an end portion of the vibrating body into contact with an object to move the object. The piezoelectric motor includes electrodes which are formed on both surfaces of the vibrating body facing in a direction intersecting a bending direction in which the end portion provided with the convex portion moves with bending vibration of the vibrating body, and to which the voltage is applied, electric wires which are coated with a non-conductive material, and apply the voltage to the electrodes, bond portions which electrically bond the electrodes and the electric wires, a storage case which stores the vibrating body, and support portions which are provided between the vibrating body and the storage case, and sandwich both surfaces of the vibrating body provided with the electrodes from the direction intersecting the bending direction of the vibrating body, wherein the bond portions are provided in the gap corresponding to the thickness of the support portions between the electrodes of the vibrating body and the storage case, and the height of the bond portions from the electrodes and the outer diameter of the electric wires are smaller than the thickness of the support portions.

In the piezoelectric motor according to the aspect of the invention, if the electric wires are bonded to the electrodes formed on both surfaces of the vibrating body and a voltage is applied, the vibrating body undergoes bending vibration to bring the convex portion in the end portion of the vibrating body into contact with the object, thereby driving the object. The vibrating body is stored in the storage case in a state where both sides (both surfaces on which the electrodes are provided) of the vibrating body are sandwiched with the support portions from the direction intersecting the bending direction of the vibrating body. The bond portions which bond the electrodes and the electric wires are provided in the gap corresponding to the thickness of the support portions between the electrodes of the vibrating body and the storage case, and the height of the bond portions from the electrodes and the outer diameter of the electric wires are smaller than the thickness of the support portions.

In this way, if both sides of the vibrating body are sandwiched by the support portions from the direction intersecting the bending direction instead of the bending direction of the vibrating body, since the support portions are deformed in a shearing direction when the vibrating body undergoes bending vibration, it is possible to suppress the transmission of the vibration of the vibrating body to the storage case compared to a case where the vibrating body is sandwiched from the bending direction. A reaction force received by the convex portion of the vibrating body when driving the object is received with rigidity when the support portions are deformed in the shearing direction, thereby supporting the vibrating body such that the vibrating body does not escapes due to the reaction force. As a result, it is possible to efficiently drive the object. If the same surfaces as the surfaces on which the electrodes of the vibrating body are provided are sandwiched by the support portions, the wiring to the electrodes is restricted. For this reason, in the piezoelectric motor according to the aspect of the invention, the wiring to the electrodes can be made using the gap corresponding to the thickness of the support portions between the electrodes of the vibrating body and the storage case. That is, if the height of the bond portions from the electrodes and the outer diameter of the electric wires are smaller than the thickness of the support portions, the wiring (bond portions and electric wires) to the electrodes is fit in the gap between the electrodes of the vibrating body and the storage case, thereby securing the wiring to the electrodes in a system in which both sides (both surfaces on which the electrodes are provided) of the vibrating body are sandwiched by the support portions from the direction intersecting the bending direction of the vibrating body.

In the piezoelectric motor according to the aspect of the invention, the vibrating body may be sandwiched by the support portions in some node portions from a plurality of node portions where the amplitude of the bending vibration is smaller than the end portion provided with the convex portion of the vibrating body or a plurality of antinode portions, such that the bond portions may be bonded to the electrodes in a node portion which is not sandwiched by the support portions.

In this way, if the node portions of the vibrating body are sandwiched by the support portions, the amplitude (the amount of movement of the convex portion) of the vibrating body in the bending vibration can increase without increasing the amount of deformation of the support portion in the shearing direction when the vibrating body undergoes bending vibration compared to a case where a portion (the end portion provided with the convex portion or the antinode portions) different from the node portions are sandwiched. This is advantageous when driving the object.

When wiring to the electrodes is made in the node portion which is not sandwiched by the support portion (the electric wires are bonded with the bond portions), it is possible to suppress interference of the wiring with the bending vibration of the vibrating body. Besides, since it is possible to suppress deviation of the wiring from the electrodes due to the bending vibration of the vibrating body, it is suitable for securing the wiring for stably applying a voltage to the vibrating body.

In the piezoelectric motor according to the aspect of the invention, the inner surface of the storage case facing the electrodes may be coated with a non-conductive material.

With this, even when distortion or the like occurs in the storage case, and the inner surface of the storage case comes into contact with the electrodes or the bond portions, it is possible to stably apply a voltage to the vibrating body without electric leakage.

In the piezoelectric motor according to the aspect of the invention, when each electrode has four regions, a first region and a second region which are connected together through a connection portion may be formed as a single body including the connection portion, and a third region and a fourth region arranged on different sides with respect to the connection portion may be connected by the electric wire intersecting the connection portion.

When the first region and the second region are connected through the electric wire (the connection portion is constituted by the electric wire), it is necessary that the third region and the fourth region three-dimensionally intersect the electric wire which connects the third region and the fourth region. Meanwhile, if the connection portion which connects the first region and the second region is formed as a single body with the electrodes, it is not necessary to provide two electric wires to three-dimensionally intersect each other, making it easy to fit the wiring to the electrodes in the gap corresponding to the thickness of the support portions between the electrodes of the vibrating body and the storage case. Therefore, it is suitable for securing the wiring to the electrodes in a system in which both sides (both surfaces on which the electrodes are provided) of the vibrating body are sandwiched by the support portions from the direction intersecting the bending direction of the vibrating body.

A driving device, a printing device, a robot hand, a robot, or the like may be constituted using the above-described piezoelectric motor.

The above-described piezoelectric motor can realize reduction in size and high driving precision. Therefore, if the driving device, the printing device, the robot hand, the robot, or the like is constituted using the above-described piezoelectric motor, it is possible to obtain a driving device, a printing device, a robot hand, a robot, or the like which is of small size and has high performance.

An electronic component inspection device described below may be constituted using the above-described piezoelectric motor. That is, an electronic component inspection device which mounts a held electronic component in an inspection socket, and inspects the electrical characteristics of the electronic component may be configured such that the electronic component is aligned with respect to the inspection socket using the above-described piezoelectric motor.

As described above, since the piezoelectric motor according to the aspect of the invention can be of small size and can realize high driving precision, it becomes possible to align the electronic component with high precision and to realize a small electronic component inspection device.

Alternatively, an electronic component inspection device may be implemented as the following form. That is, an electronic component inspection device which mounts a held electronic component in an inspection socket, and inspects the electrical characteristics of the electronic component may be configured to include a piezoelectric motor which aligns the electronic component with respect to the inspection socket, wherein the piezoelectric motor includes a vibrating body which is formed to contain a piezoelectric material, and if a voltage is applied, undergoes bending vibration, a convex portion which is provided in an end portion of the vibrating body, electrodes which are formed on both surfaces of the vibrating body facing in a direction intersecting a bending direction in which the end portion provided with the convex portion moves with bending vibration of the vibrating body, and to which the voltage is applied, electric wires which are coated with a non-conductive material, and apply the voltage to the electrodes, bond portions which electrically bond the electrodes and the electric wires, a storage case which stores the vibrating body, and support portions which are provided between the vibrating body and the storage case, and sandwich both surfaces of the vibrating body provided with the electrodes from the direction intersecting the bending direction of the vibrating body, the bond portions are provided in the gap corresponding to the thickness of the support portions between the electrodes of the vibrating body and the storage case, and the height of the bond portions from the electrodes and the outer diameter of the electric wires are smaller than the thickness of the support portions.

An electronic component inspection device may be implemented as the following form. That is, an electronic component inspection device may be configured to include an inspection socket in which an electronic component is mounted, and the electrical characteristics of the electronic component are inspected, a holding device which holds an electronic component, a moving device which moves the holding device in the direction of three axes in total of a first axis and a second axis perpendicular to each other and a third axis perpendicular to the first axis and the second axis, an imaging device which is provided on the first axis or the second axis when viewed from the inspection socket, and detects a position in the directions of the first axis and the second axis and an angle around the third axis for the electronic component mounted in the inspection socket as the posture of the electronic component, an upstream-side stage which conveys the electronic component from the inspection socket to a predetermined position on the first axis or the second axis connecting the imaging device, a downstream-side stage which conveys the electronic component from a predetermined position opposite to the side on which the imaging device is provided when viewed from the inspection socket, and a control device which controls the operation of the moving device, wherein the control device includes a first control unit which moves the holding device holding the electronic component conveyed by the upstream-side stage onto the imaging device, a second control unit which moves the holding device to mount the electronic component whose posture is confirmed by the imaging device in the inspection socket, and a third control unit which moves the holding device to place the electronic component whose electrical characteristics are inspected in the inspection socket from the inspection socket to the downstream-side stage, the holding device has a first piezoelectric motor which moves the electronic component in the direction of the first axis on the basis of the posture of the electronic component detected by the imaging device, a second piezoelectric motor which moves the electronic component in the direction of the second axis on the basis of the posture of the electronic component detected by the imaging device, and a third piezoelectric motor which rotates the electronic component around the third axis on the basis of the posture of the electronic component detected by the imaging device, and the first to third piezoelectric motors are the above-described piezoelectric motor.

The electronic component inspection device having this configuration can mount the electronic component in the inspection socket after the posture of the electronic component is adjusted by means of the first to third piezoelectric motors provided in the holding device. Since the above-described piezoelectric motor can be of small size and can drive the object with high precision, the piezoelectric motor is particularly excellent as the first to third piezoelectric motors provided in the holding device.

An electronic component conveying device described below may be constituted using the piezoelectric motor according to the aspect of the invention. That is, an electronic component conveying device which conveys a held electronic component may be configured such that the electronic component is aligned by means of the piezoelectric motor according to the aspect of the invention.

As described above, since the piezoelectric motor according to the aspect of the invention can realize reduction in size and high driving precision, it becomes possible to align the electronic component with high precision and to realize a small electronic component conveying device.

Alternatively, an electronic component conveying device may be implemented as the following form. That is, an electronic component conveying device which conveys a held electronic component may be configured to include a piezoelectric motor which aligns the electronic component, wherein the piezoelectric motor includes a vibrating body which is formed to contain a piezoelectric material, and if a voltage is applied, undergoes bending vibration, a convex portion which is provided in an end portion of the vibrating body, electrodes which are formed on both surfaces of the vibrating body facing in a direction intersecting a bending direction in which the end portion provided with the convex portion moves with bending vibration of the vibrating body, and to which the voltage is applied, electric wires which are coated with a non-conductive material, and apply the voltage to the electrodes, bond portions which electrically bond the electrodes and the electric wires, a storage case which stores the vibrating body, and support portions which are provided between the vibrating body and the storage case, and sandwich both surfaces of the vibrating body provided with the electrodes from the direction intersecting the bending direction of the vibrating body, the bond portions are provided in the gap corresponding to the thickness of the support portions between the electrodes of the vibrating body and the storage case, and the height of the bond portions from the electrodes and the outer diameter of the electric wires are smaller than the thickness of the support portions.

An electronic component conveying device may be implemented as the following form. That is, an electronic component conveying device may be configured to include a holding device which holds an electronic component, a moving device which moves the holding device in the directions of three axes in total of a first axis and a second axis perpendicular to each other and a third axis perpendicular to the first axis and the second axis, and a control device which controls the operation of the moving device, wherein the holding device has a first piezoelectric motor which moves the electronic component in the direction of the first axis, a second piezoelectric motor which moves the electronic component in the direction of the second axis, and a third piezoelectric motor which rotates the electronic component around the third axis, and the first to third piezoelectric motors are the above-described piezoelectric motor.

### BRIEF DESCRIPTION OF THE DRAWINGS

The invention will be described with reference to the accompanying drawings, wherein like numbers reference like elements.

FIGS. 1A and 1B are explanatory views showing the broad configuration of a piezoelectric motor of this example.

FIG. 2 is an exploded view showing the structure of a main portion of this example.

FIG. 3 is an explanatory view showing wiring for applying a voltage to a vibrating body of this example in which a front electrode and a rear electrode are provided.

FIGS. 4A to 4C are explanatory views showing an operation principle of a piezoelectric motor.

FIG. 5 is an explanatory view showing a mode in which wiring is made to a front electrode and a rear electrode of the vibrating body of this example by taking a section of a main portion along an X-Z plane.

FIG. 6 is an explanatory view showing node portions of a vibrating body.

FIGS. 7A and 7B is an explanatory view showing a front electrode provided in a vibrating body of a modification and wiring to the front electrode.

FIG. 8 is a perspective view illustrating an electronic component inspection device embedded with a piezoelectric motor of this example.

FIG. 9 is an explanatory view of a fine adjustment mechanism embedded in a holding device.

FIG. 10 is a perspective view illustrating a printing device embedded with a piezoelectric motor of this example.

FIG. 11 is an explanatory view illustrating a robot hand embedded with a piezoelectric motor of this example.

FIG. 12 is an explanatory view illustrating a robot including a robot hand.

FIG. 13 is an explanatory view showing an example where node portions of a vibrating body are sandwiched by support portions in a form different from an example.

### DESCRIPTION OF EXEMPLARY EMBODIMENTS

Hereinafter, in order to clarify the content of the invention, an example will be described in the following sequence.

A. Device Configuration

B. Operation Principle of Piezoelectric Motor

C. Securing of Wiring to Front Electrode and Rear Electrode

D. Modifications

E. Application Examples

### A. Device Configuration

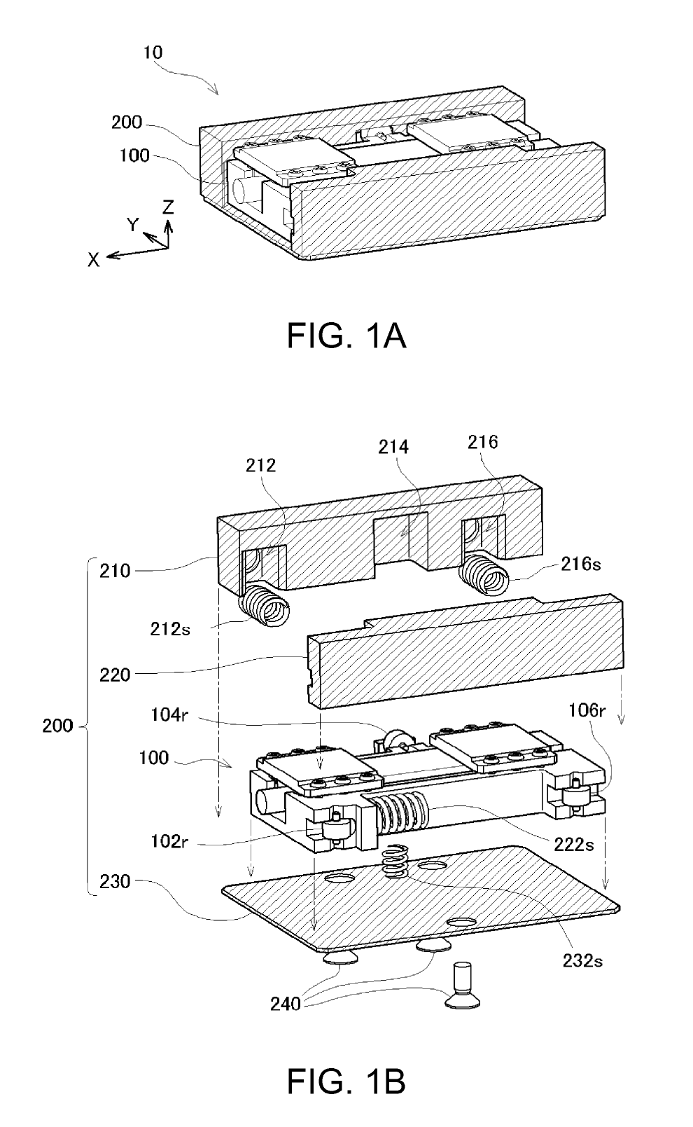

FIGS. 1A and 1B are explanatory views showing the broad configuration of a piezoelectric motor 10 of this example. FIG. 1A is an overall view of the piezoelectric motor 10 of this example, and FIG. 1B is an exploded view. As shown in FIG. 1A, the piezoelectric motor 10 of this example broadly has a main portion 100 and a base portion 200. The main portion 100 is attached into the base portion 200, and is movable in one direction in this state. In this specification, the moving direction of the main portion 100 is referred to as an X direction. As shown in the drawing, directions perpendicular to the X direction are respectively referred to as a Y direction and a Z direction.

The main portion 100 and the base portion 200 respectively have a plurality of components. For example, the base portion 200 is configured such that a first sidewall block 210 and a second sidewall block 220 are fastened to both sides of an upper surface of a substrate 230 substantially having a rectangular shape by locking screws 240 (see FIG. 1B). When assembling the piezoelectric motor 10, the first sidewall block 210 and the second sidewall block 220 are attached to the substrate 230 by the locking screws 240 from above the main portion 100.

The first sidewall block 210 has three concave portions of a front housing 212, a central housing 214, and a rear housing 216. When attaching the first sidewall block 210 to the substrate 230, attachment is made in a state where a front-side pressure spring 212s is stored in the front housing 212, and a rear-side pressure spring 216s is stored in the rear housing 216. As a result, the main portion 100 is in a state of being pressed against the second sidewall block 220 by the front-side pressure spring 212s and the rear-side pressure spring 216s. A front roller 102r and a rear roller 106r are attached onto the lateral surface side of the main portion 100 facing the second sidewall block 220. A pressure spring 222s is provided on the lateral surface of the main portion 100. The pressure spring 222s presses the main portion 100 at a location on the rear side of the front roller 102r in the X direction.

A pressing roller 104r in the Z direction (upward in the drawing) is provided on the lateral surface of the main portion 100 opposite to the side on which the front roller 102r and the rear roller 106r are provided. In a state where the first sidewall block 210 is attached, the pressing roller 104r is stored in the central housing 214 of the first sidewall block 210. A pressing spring 232s is provided between the rear side of a portion where the pressing roller 104r of the main portion 100 is provided and the substrate 230. For this reason, the pressing roller 104r is in a state of being pressed in the Z direction (upward in the drawing) with respect to the inner surface of the central housing 214.

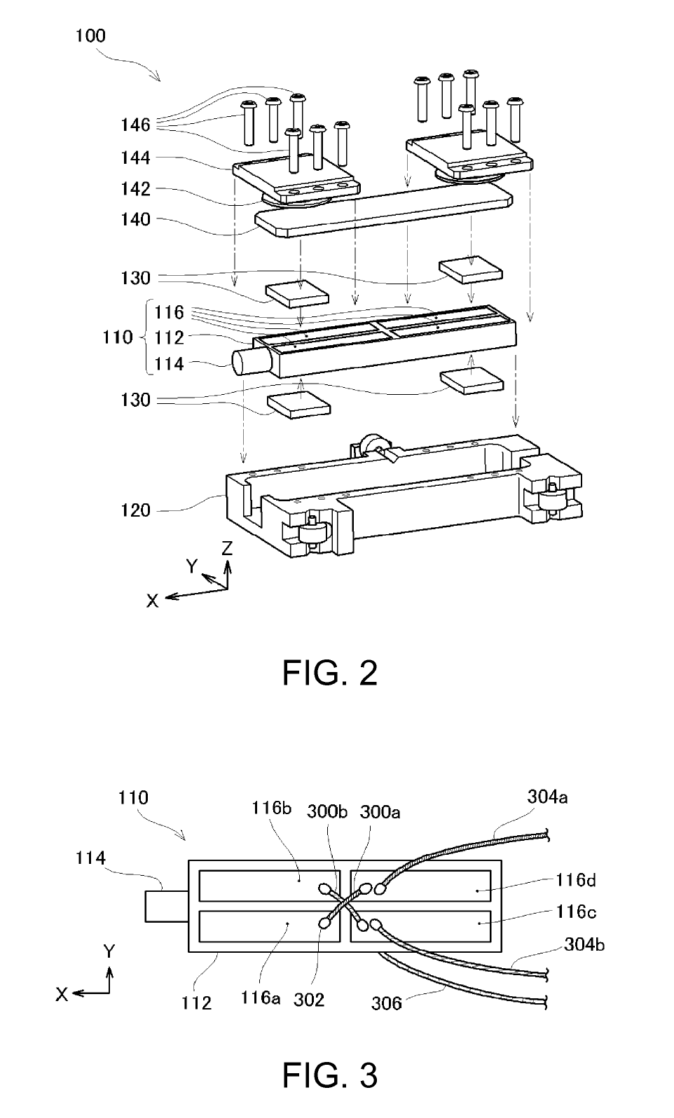

FIG. 2 is an exploded view showing the structure of the main portion 100 of this example. The main portion 100 broadly has a structure in which a vibration unit 110 is stored in a vibrating body case 120. The vibration unit 110 has a vibrating body 112 which is formed of a piezoelectric material to have a rectangular parallelepiped shape, a ceramic driving convex portion 114 which is attached to an end surface in a longitudinal direction (X direction) of the vibrating body 112, four front electrodes 116 which are provided by quartering one surface of the vibrating body 112 facing in the Z direction, and the like. Though not shown in FIG. 2, in the surface opposite to the side on which the four front electrodes 116 are provided, a rear electrode which substantially covers the entire surface is provided. The rear electrode is grounded.

As described below, the vibrating body 112 vibrates when a voltage is applied. The driving convex portion 114 of this example corresponds to the “convex portion” according to the invention, and the front electrodes 116 and the rear electrode of this example correspond to the “electrodes” according to the invention.

The vibrating body 112 is stored in a vibrating body case 120 in a state where both surfaces (in FIG. 2, both surfaces in the Z direction) in which the front electrodes 116 and the rear electrode are provided are sandwiched by resin support members 130. Lid plates 140, disk springs 142, and pressing plates 144 are laminated from above the support members 130 on the front electrode 116 side, and the pressing plates 144 are fastened to the vibrating body case 120 by locking screws 146. For this reason, while the vibration unit 110 is pressed by the spring force of the disk springs 142 through the lid plates 140 and the support members 130, the resin support members 130 are shear-deformed, such that the vibrating body 112 is stored in the vibrating body case 120 in a vibratable state. The vibrating body case 120 and the lid plates 140 of this example correspond to the “storage case” according to the invention, and the support members 130 of this example correspond to the “support portion” according to the invention.

FIG. 3 is an explanatory view showing wiring for applying a voltage to the vibrating body 112 provided with the front electrodes 116 and the rear electrode. As shown in the drawing, the four front electrodes 116 are provided in one surface of both surfaces (both surfaces with which the support members 130 are in contact) of the vibrating body 112 in the Z direction as sets of diagonally opposite two front electrodes 116 (a set of front electrode 116a and front electrode 116d and a set of front electrode 116b and front electrode 116c), and the front electrodes 116 of the respective sets are connected by inter-electrode electric wires 300a and 300b. The inter-electrode electric wires 300a and 300b which three-dimensionally intersect each other in the up-down direction (Z direction) are coated with an insulating material, and are bonded to the front electrodes 116 by solders 302. The front electrodes 116 (front electrode 116c and front electrode 116d) on the side away from the driving convex portion 114 from the front electrodes 116 of the respective sets are connected to an external power supply (not shown) by external electric wires 304a and 304b. Similarly to the inter-electrode electric wires 300a and 300b, the external electric wires 304a and 304b are bonded to the front electrodes 116 by the solders 302 using electric wires coated with an insulating material.

As described above, in the surface of the vibrating body 112 opposite to the side on which the four front electrodes 116 are provided, the rear electrode which substantially covers the entire surface is provided, and a ground electric wire 306 for connection to the ground is bonded to the rear electrode by the solder 302. The inter-electrode electric wires 300, the external electric wires 304, and the ground electric wires 306 of this example correspond to the “electric wires” according to the invention, and the solders 302 of this example correspond to the “bond portions” according to the invention.

### B. Operation Principle of Piezoelectric Motor

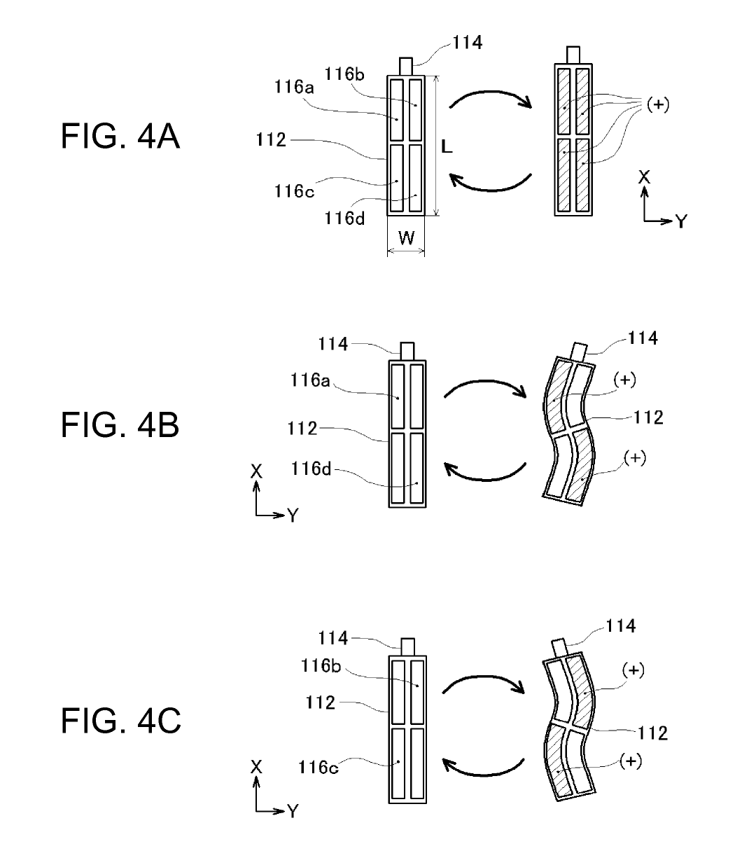

FIGS. 4A to 4C are explanatory views showing the operation principle of the piezoelectric motor 10. The piezoelectric motor 10 operates by the elliptical motion of the driving convex portion 114 of the vibration unit 110 when a voltage is applied to the front electrodes 116 of the vibration unit 110 in a given period. The elliptical motion of the driving convex portion 114 of the vibration unit 110 is for the following reason.

First, as well known in the art, the vibrating body 112 expands if a positive voltage is applied. Accordingly, as shown in FIG. 4A, if a positive voltage is applied to all of the four front electrodes 116, and the applied voltage is then released repeatedly, the vibrating body 112 repeatedly expands and contracts in the longitudinal direction (X direction). In this way, the operation in which the vibrating body 112 repeatedly expands and contracts in the longitudinal direction (X direction) is referred to as “stretching vibration”. If the frequency at which the positive voltage is applied is changed, the amount of expansion and contraction rapidly increases when a specific frequency is reached, and a type of resonance phenomenon occurs. The frequency (resonance frequency) at which resonance occurs due to stretching vibration is determined by the physical property of the vibrating body 112 and the dimension (width W, length L, thickness T) of the vibrating body 112.

As shown in FIG. 4B or 4C, the positive voltage is applied to the sets of diagonally opposite two front electrodes 116 (a set of front electrode 116a and front electrode 116d or a set of front electrode 116b and front electrode 116c) in a given period. When this happens, the vibrating body 112 repeats an operation such that the tip portion in the longitudinal direction (X direction) (a portion to which the driving convex portion 114 is attached) shakes the head thereof in the left-right direction (Y direction) of the drawing. For example, as shown in FIG. 4B, each time the positive voltage is applied to the set of front electrode 116a and front electrode 116d, the vibrating body 112 repeats an operation such that the tip portion in the longitudinal direction moves in the right direction. As shown in FIG. 4C, each time the positive voltage is applied to the set of front electrode 116b and front electrode 116c, the vibrating body 112 repeats an operation such that the tip portion in the longitudinal direction moves in the left direction. This operation of the vibrating body 112 is referred to as “bending vibration”. In regard to the bending vibration, there is the resonance frequency which is determined by the physical property of the vibrating body 112 and the dimension (width W, length L, thickness T) of the vibrating body 112. Accordingly, if the positive voltage is applied to the diagonally opposite two front electrodes 116 at the resonance frequency, the vibrating body 112 largely vibrates the head thereof in the right direction or the left direction (Y direction).

The resonance frequency of the stretching vibration shown in FIG. 4A and the resonance frequency of the bending vibration shown in FIG. 4B or 4C are determined by the physical property of the vibrating body 112 or the dimension (width W, length L, thickness T) of the vibrating body 112. Accordingly, if the dimension (width W, length L, thickness T) of the vibrating body 112 is appropriately selected, the two resonance frequencies can coincide with each other. If the voltage in the form of the bending vibration shown in FIG. 4B or 4C is applied to the vibrating body 112 at the resonance frequency, the bending vibration shown in FIG. 4B or 4C occurs, and the stretching vibration of FIG. 4A is induced by resonance. As a result, when a voltage is applied to the set of front electrode 116a and front electrode 116d in the form shown in FIG. 4B, the tip portion (a portion to which the driving convex portion 114 is attached) of the vibrating body 112 performs an operation (elliptical motion) to draw an ellipse in a clockwise direction in the drawing. When a voltage is applied to the set of front electrode 116b and front electrode 116c in the form shown in FIG. 4C, the tip portion of the vibrating body 112 performs an elliptical motion in a counterclockwise direction in the drawing.

The piezoelectric motor 10 drives the object using the elliptical motion. That is, the elliptical motion is generated in a state where the driving convex portion 114 of the vibrating body 112 is pressed against the object. In this case, the driving convex portion 114 repeats an operation to move from left to right (or from right to left) in a state of being pressed against the object when the vibrating body 112 expands, and to return the original position in a state of being away from the object when the vibrating body 112 contracts. As a result, the object is driven in one direction by a frictional force applied from the driving convex portion 114. Since the driving force applied to the object is equal to a frictional force which is generated between the object and the driving convex portion 114, the magnitude of the driving force is determined by a frictional coefficient between the driving convex portion 114 and the object and a force when the driving convex portion 114 is pressed against the object.

As will be apparent from the operation principle of the piezoelectric motor 10 described above, it is necessary that the piezoelectric motor 10 is used in a state where the driving convex portion 114 is pressed against the object. For this reason, in the piezoelectric motor 10 of this example, the main portion 100 including the driving convex portion 114 is movable with respect to the base portion 200, and the driving convex portion 114 protruding the main portion 100 is pressed against the object by the pressure spring 222s provided between the main portion 100 and the base portion 200 (see FIGS. 1A and 1B).

If the object is driven, the driving convex portion 114 receives a reaction force from the object. The reaction force is transmitted to the main portion 100. As described above, while the main portion 100 should be movable with respect to the base portion 200, if the main portion 100 escapes in a direction perpendicular to the moving direction with the reaction force received during driving, a sufficient driving force cannot be transmitted to the object. If the main portion 100 escapes, the amount of movement of the driving convex portion 114 decreases, such that the amount of driving of the object becomes small. Since the amount of escape of the main portion 100 may not be constantly stable, the amount of driving of the object becomes unstable. Accordingly, as shown in FIGS. 1A and 1B, in the piezoelectric motor 10 of this example, the main portion 100 is pressed against the second sidewall block 220 from the direction perpendicular to the moving direction of the main portion 100 by the front-side pressure spring 212s and the rear-side pressure spring 216s.

The vibrating body 112 should be stored in the vibrating body case 120 in a state where the vibration (stretching vibration and bending vibration) of the vibrating body 112 is permitted such that the driving convex portion 114 performs an elliptical motion. Accordingly, as shown in FIG. 2, in the piezoelectric motor 10 of this example, the vibrating body 112 is stored in the vibrating body case 120 in a state where the vibrating body 112 is sandwiched by the support members 130 from the direction (Z direction: the direction in which both surfaces on which the front electrodes 116 and the rear electrode of the vibration unit 110 are provided face) intersecting the bending direction (Y direction: the direction in which the end portion provided with the driving convex portion 114 moves) of the vibrating body 112. When the vibrating body 112 vibrates with application of a voltage, the support members 130 are deformed in the shearing direction to permit the vibration of the vibrating body 112, thereby generating the elliptical motion of the driving convex portion 114. The vibrating body 112 is sandwiched by the support members 130 from the direction intersecting the bending direction, it is possible to suppress a loss of energy due to the transmission of the bending vibration to the vibrating body case 120 compared to a case where the vibrating body 112 is sandwiched from the bending direction, thereby efficiently driving the object.

The support members 130 are formed of a resin material, such as polyimide, and as the support members 130 increase in thickness, deformation (shear deformation) in the shearing direction easily occurs to increase the allowable amplitude (the degree of freedom of vibration) of the vibrating body 112. When this happens, the amount of movement of the driving convex portion 114 increases, the amount of driving or the driving speed of the object is improved, thereby advantageously affecting the driving of the object. Meanwhile, the support members 130 support the reaction force received by the driving convex portion 114 from the object with rigidity when being deformed in the shearing direction. If the support members 130 increase in thickness, while shear deformation easily occurs, rigidity which supports the reaction force from the object is lowered to decrease the driving of the object. In this way, it is necessary that the support members 130 have an appropriate thickness so as to have appropriate rigidity which supports the reaction force received by the driving convex portion 114 from the object while permitting the vibration of the vibrating body 112 due to shear deformation. In the piezoelectric motor of this example, the vibrating body 112 (width: 7.5 mm, length: 30.0 mm, thickness: 3.0 mm) is sandwiched by the support members 130 having a thickness of 1.0 mm from both sides.

As described above, the front electrodes 116 and the rear electrode are provided on both surfaces of the vibrating body 112 sandwiched by the support members 130 (both surfaces of the vibrating body 112 facing in the direction intersecting the bending direction), and various electric wires (the inter-electrode wires 300a and 300b, the external electric wires 304a and 304b, and the ground electric wire 306) for applying a voltage to the vibrating body 112 are bonded to the electrodes by the solders 302. However, when the same surfaces as the surfaces of the vibrating body 112 on which the front electrodes 116 and the rear electrode are provided are sandwiched by the support members 130, there is a restriction on securing the wiring to the front electrodes 116 and the rear electrode. Accordingly, in the piezoelectric motor 10 of this example, the wiring to the front electrode 116a and the rear electrode of the vibrating body 112 is secured as follows.

### C. Securing of Wiring to Front Electrode and Rear Electrode

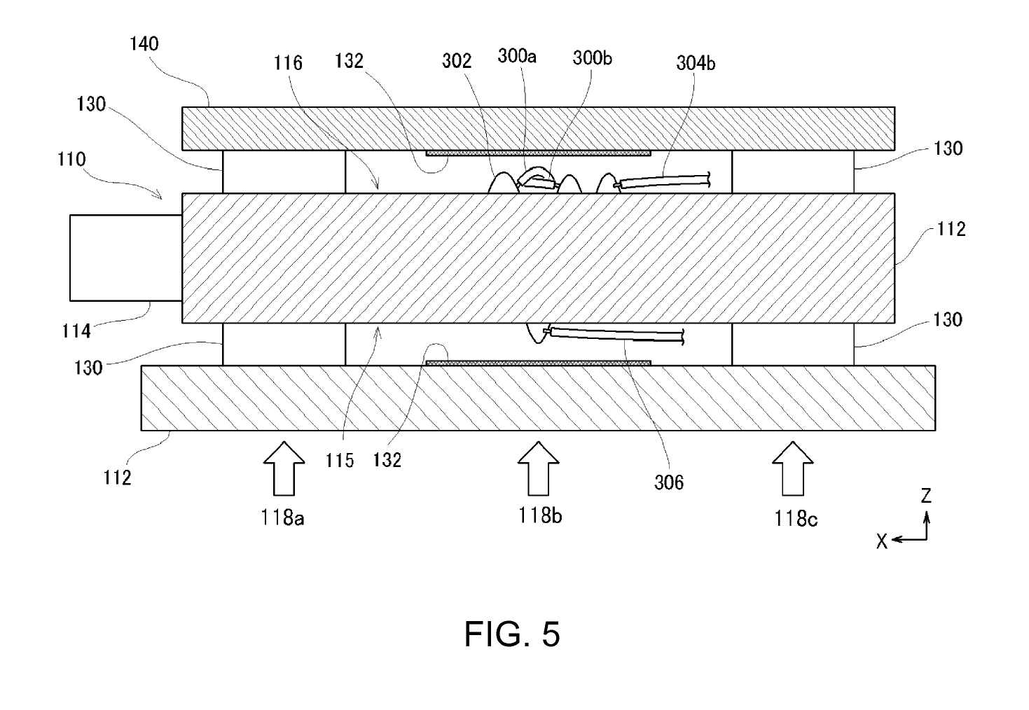

FIG. 5 is an explanatory view showing a mode in which wiring to the front electrodes 116 and the rear electrode 115 of the vibrating body 112 is made by taking a section of the main portion 100 along an X-Z plane. As shown in the drawing, the space (gap) corresponding to the thickness of the support members 130 is formed between the front electrodes 116 of the vibrating body 112 and the lid plates 140. As described above, the thickness of the support members 130 is set taking into consideration ease of shear deformation for permitting the vibration of the vibrating body 112 and appropriate rigidity which supports the reaction force received by the driving convex portion 114 from the object. In the piezoelectric motor 10 of this example, the support members 130 having a thickness of 1.0 mm are used. The wiring to the front electrodes 116 is made using the gap corresponding to the thickness of the support members 130. That is, as shown in FIG. 3, the four front electrodes 116 are provided in the vibrating body 112 such that the sets of diagonally opposite two front electrodes 116 (a set of front electrode 116a and front electrode 116d and a set of front electrode 116b and front electrode 116c) are connected by the inter-electrode electric wires 300a and 300b, and the inter-electrode electric wires 300a and 300b three-dimensionally intersect each other in the up-down direction (Z direction) and are bonded to the front electrodes 116 by the solders 302. The external electric wires 304a and 304b are bonded to the front electrodes 116 (front electrode 116c and front electrode 116d) by the solders 302. For the inter-electrode electric wires 300a and 300b and the external electric wires 304a and 304b, electric wires having an outer diameter (for example, outer diameter: 0.27 mm) smaller than the thickness of the support members 130 are used. The thickness (the height from the front electrodes 116) of the solders 302 which bond various electric wires to the front electrodes 116 is smaller than the thickness of the support members 130. For this reason, the wiring (the solders 302, the inter-electrode electric wires 300a and 300b, the external electric wires 304a and 304b) to the front electrodes 116 is fit in the gap corresponding to the thickness of the support members 130.

Similarly, the gap corresponding to the thickness of the support members 130 is formed between the bottom surface of the vibrating body case 120 and the rear electrode 115 of the vibrating body 112. As described above, in the surface opposite to the side on which the four front electrodes 116 of the vibrating body 112 are provided, the rear electrode 115 which substantially covers the entire surface is provided, and the ground electric wire 306 is bonded to the rear electrode 115 by the solder 302. Similarly to the external electric wires 304a and 304b, an electric wire having an outer diameter smaller than the thickness of the support members 130 is used for the ground electric wire 306. Since the thickness (the height from the rear electrode 115) of the solder 302 which bonds the ground electric wire 306 to the rear electrode 115 is smaller than the thickness of the support members 130, the wiring (the solders 302, the ground electric wire 306) to the rear electrode 115 can be fit in the gap corresponding to the thickness of the support members 130.

As described above, in the piezoelectric motor 10 of this example, the wiring (the solders 302, the inter-electrode electric wires 300a and 300b, the external electric wires 304a and 304b) to the front electrodes 116 and the wiring (the solder 302, the ground electric wire 306) to the rear electrode 115 can be fit in the gap corresponding to the thickness of the support members 130. Therefore, in a system in which both sides (both surfaces on which the front electrodes 116 and the rear electrode 115 are provided) of the vibrating body 112 are sandwiched by the support members 130 from the direction intersecting the bending direction of the vibrating body 112, it is possible to secure the wiring to the front electrodes 116 and the rear electrode 115.

As shown in FIG. 5, an insulating sheet 132 formed of an insulating material is pasted on the inner surface of the lid plate 140 facing the front electrodes 116 and the inner surface of the vibrating body case 120 facing the rear electrode 115. For this reason, even distortion occurs in the lid plate 140 or the vibrating body case 120, and the inner surface of the lid plate 140 comes into contact with the solder 302 of the front electrodes 116 or the inner surface of the vibrating body case 120 comes into contact with the solder 302 of the rear electrode 115, it is possible to stably apply a voltage to the vibrating body 112 without electric leakage.

In the piezoelectric motor 10 of this example, portions (node portions) where the amplitude of the bending vibration is smaller than the end portion provided with the driving convex portion 114 of the vibrating body 112 are sandwiched by the support members 130, and the wiring to the respective electrodes (the front electrodes 116 and the rear electrode 115) is made in the node portion different from the node portions which are sandwiched by the support members 130. In this way, it is possible to secure more stable wiring. Hereinafter, this point will be described supportively.

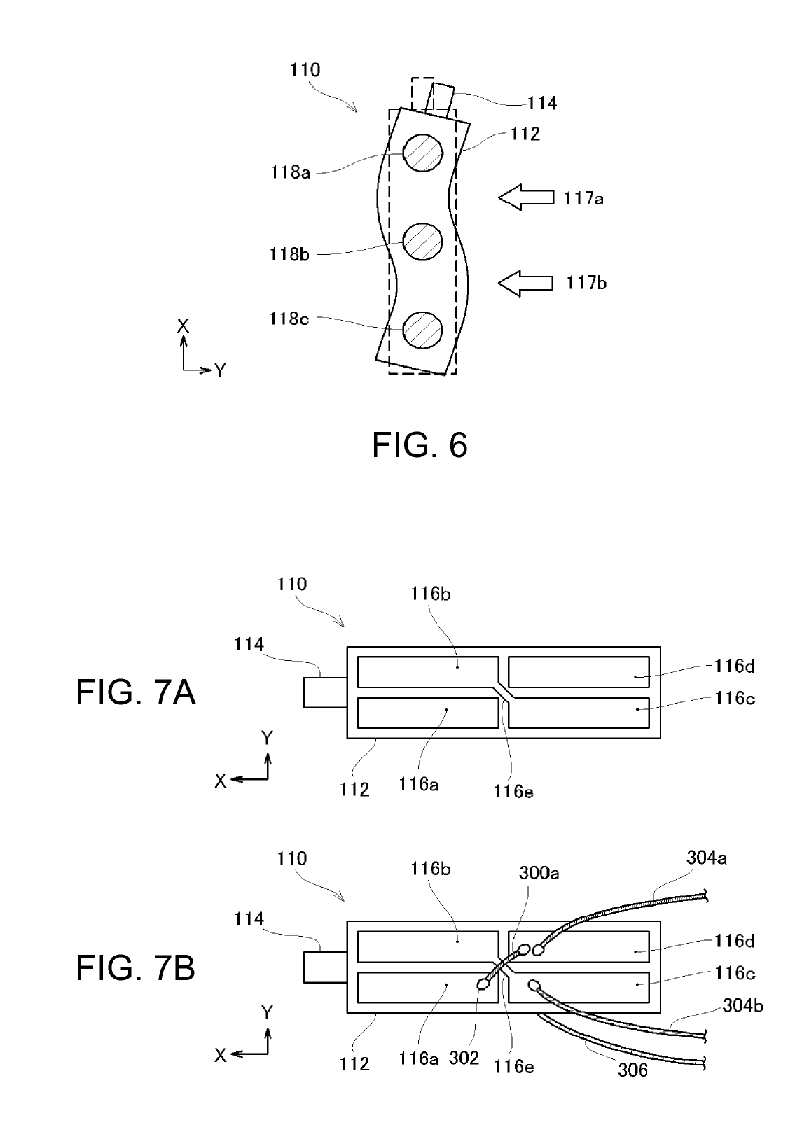

FIG. 6 is an explanatory view showing the node portions of the vibrating body 112. As described above with reference to FIGS. 4A to 4C, if the positive voltage is applied to the sets of diagonally opposite two front electrodes 116 (a set of front electrode 116a and front electrode 116d and a set of front electrode 116b and front electrode 116c) of the four front electrodes 116 in a given period, the vibrating body 112 repeatedly undergoes bending vibration such that the driving convex portion 114 shakes the head thereof in the left-right direction (Y direction) in the drawing. In FIG. 6, a state where the positive voltage is not applied to the vibrating body 112 is indicated by a broken line, and a state where the positive voltage is applied to the set of front electrode 116a and front electrode 116d of the vibrating body 112 and the driving convex portion 114 moves in the right direction is indicated by a solid line.

The vibrating body 112 which undergoes the bending vibration in the above-described manner does not vibrates uniformly as a whole (moves in the Y direction), and as shown in FIG. 6, has antinode portions 117 (117a and 117b) which vibrate at the same amplitude as the tip portion provided with the driving convex portion 114, and node portions 118 where the amplitude of the bending vibration is smaller than the tip portion or the antinode portions 117. The vibrating body 112 of this example has three node portions 118 of a center node portion 118b at the center of the vibrating body 112 in the longitudinal direction (X direction), a front node portion 118a close to the driving convex portion 114, and a rear node portion 118c away from the driving convex portion 114.

The front node portion 118a and the rear node portion 118c from among the three node portions 118 are portions in which the vibrating body 112 is sandwiched by the support members 130 (see FIG. 5). In this way, the node portions 118 of the vibrating body 112 are sandwiched by the support members 130, the amplitude (the amount of movement of the driving convex portion 114) of the bending vibration of the vibrating body 112 can increase compared to a case where portions (antinode portions 117 or the like) different from the node portions 118 are sandwiched without increasing the amount of deformation of the support members 130 in the shearing direction when the vibrating body 112 undergoes the bending vibration. Therefore, this is advantageous when driving the object.

The center node portion 118b which is not sandwiched by the support members 130 faces the gap corresponding to the thickness of the support members 130 (see FIG. 5). In the piezoelectric motor 10 of this example, the wiring (the bonding of the inter-electrode electric wires 300a and 300b and the external electric wires 304a and 304b by the solders 302) to the front electrodes 116 and the wiring (the bonding of the ground electric wire 306 by the solder 302) to the rear electrode 115 are made in the center node portion 118b. In this way, if the wiring to the respective electrodes is made in the node portion 118, it is possible to suppress interference of the wiring with the bending vibration of the vibrating body 112. Since it is possible to suppress deviation of the electric wires from the electrodes due to the bending vibration of the vibrating body 112, it is suitable for securing the wiring for stably applying a voltage to the vibrating body 112.

### D. Modifications

Hereinafter, modifications of the piezoelectric motor 10 of the foregoing example will be described. In the description of the modifications, the same parts as those in the foregoing example are represented by the same reference numerals as the foregoing examples, and detailed description thereof will not be repeated.

FIGS. 7A and 7B are explanatory views showing front electrodes 116 provided in a vibrating body 112 of a modification and wiring to the front electrodes 116. First, FIG. 7A shows a state before an inter-electrode electric wire 300 or an external electric wire 304 is bonded to a front electrode 116 by solders 302. In the vibrating body 112 of the modification, as the above-described example, the front electrode 116 has four regions. Of these, a front electrode 116b and a front electrode 116c are connected together in advance by a connection portion 116e which is formed as a single body when forming the front electrode 116.

In the vibrating body 112 of the modification, during wiring to the front electrode 116, as shown in FIG. 7B, a front electrode 116a and a front electrode 116d may be connected together by an inter-electrode electric wire 300a. Since the front electrode 116b and the front electrode 116c are connected together in advance by the connection portion 116e, as in the above-described example, it is not necessary to connect the front electrode 116b and the front electrode 116c by the inter-electrode electric wire 300b (see FIG. 3). For this reason, it is possible to simplify a wiring operation to the front electrode 116 compared to the above-described example. The front electrode 116b and the front electrode 116c of the modification correspond to the “first region” and the “second region” according to the invention, and the front electrode 116a and the front electrode 116d of the modification correspond to the “third region” and the “fourth region” according to the invention.

While in the vibrating body 112 of the above-described example, the two inter-electrode electric wires 300a and 300b three-dimensionally intersect each other in the up-down direction (Z direction) (see FIG. 5), in the vibrating body 112 of the modification, the connection portion 116e is formed as a single body when forming the front electrode 116, instead of the inter-electrode electric wire 300b. Since it is not necessary to provide the two inter-electrode electric wires 300a and 300b to three-dimensionally intersect each other, the wiring (the solder 302, the inter-electrode electric wire 300a, the external electric wires 304a and 304b) of the front electrode is easily fit in the gap corresponding to the thickness of the support members 130 between the front electrode 116 of the vibrating body 112 and the lid plate 140. Accordingly, it is suitable for securing wiring to the front electrode 116 particularly in a system in which both surfaces (both surfaces on which the front electrode 116 and the rear electrode 115 are provided) of the vibrating body 112 are sandwiched by the support members 130 from the direction intersecting the bending direction of the vibrating body 112.

### E. Application Examples

The piezoelectric motor 10 of this example or the piezoelectric motor 10 of the modification can be of small size and can drive the object with high precision. Therefore, the piezoelectric motor can be suitably incorporated as a driving device of the following device.

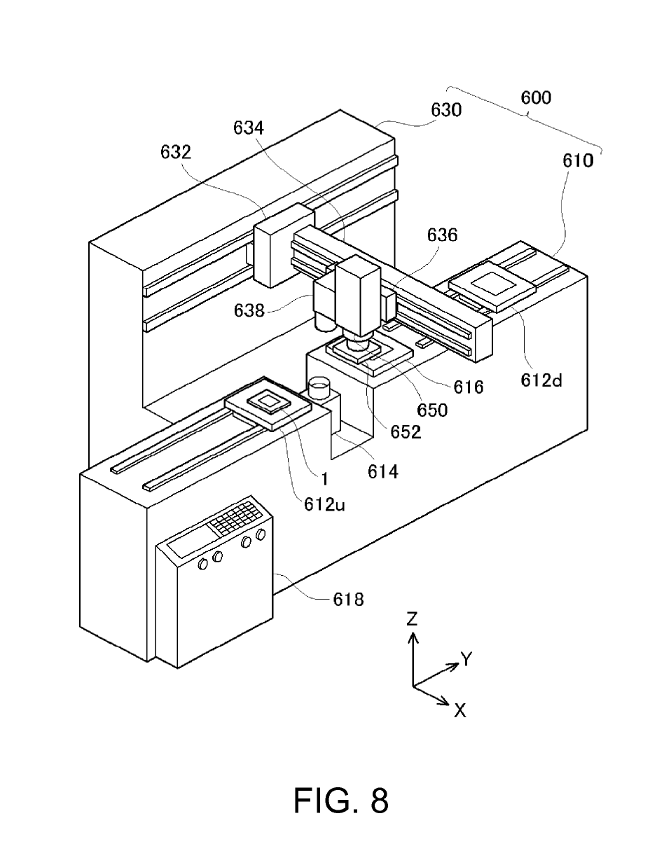

FIG. 8 is a perspective view illustrating an electronic component inspection device 600 in which the piezoelectric motor 10 of this example is incorporated. The electronic component inspection device 600 broadly includes a base 610, and a support 630 which is provided upright on the lateral surface of the base 610. On the upper surface of the base 610 are provided an upstream-side stage 612u which is conveyed with an electronic component 1 to be inspected placed thereon, and a downstream-side stage 612d which is conveyed with the inspected electronic component 1 placed thereon. Between the upstream-side stage 612u and the downstream-side stage 612d are provided an imaging device 614 which confirms the posture of the electronic component 1, and an inspection table 616 on which the electronic component 1 is set so as to inspect electrical characteristics. Representative examples of the electronic component 1 include “semiconductors”, “display devices, such as CLD or OLED”, “crystal devices”, “various sensors”, “ink jet heads”, “various MEMS devices”, and the like. The inspection table 616 of this example corresponds to the “inspection socket” according to the invention.

A Y stage 632 is provided in the support 630 to be movable in a direction (Y direction) parallel to the upstream-side stage 612u and the downstream-side stage 612d of the base 610, and an arm portion 634 extends from the Y stage 632 in a direction (X direction) toward the base 610. An X stage 636 is provided on the lateral surface of the arm portion 634 to be movable in the X direction. An imaging camera 638 and a holding device 650 embedded with a Z stage movable in an up-down direction (Z direction) are provided in the X stage 636. A holding portion 652 which holds the electronic component 1 is provided at the tip of the holding device 650. A control device 618 which controls the overall operation of the electronic component inspection device 600 is provided on the front surface side of the base 610. In this example, the Y stage 632 provided in the support 630, the arm portion 634, the X stage 636, or the holding device 650 corresponds to the “electronic component conveying device” according to the invention. The X stage 636, the Y stage 632, and the Z stage embedded in the holding device 650 correspond to the “moving device” according to the invention. The control device 618 of this example corresponds to the “first control unit”, the “second control unit”, and the “third control unit” according to the invention.

The electronic component inspection device 600 having the above configuration inspects the electronic component 1 as follows. First, the electronic component 1 to be inspected is placed on the upstream-side stage 612u and moves near the inspection table 616. Next, the Y stage 632 and the X stage 636 are driven to move the holding device 650 to a position directly above the electronic component 1 placed on the upstream-side stage 612u. At this time, the position of the electronic component 1 can be confirmed using the imaging camera 638. The holding device 650 falls using the Z stage embedded in the holding device 650, if the electronic component 1 is held using the holding portion 652, the holding device 650 moves directly above the imaging device 614, and the posture of the electronic component 1 is confirmed using the imaging device 614. Subsequently, the posture of the electronic component 1 is adjusted using a fine adjustment mechanism embedded in the holding device 650. The holding device 650 moves to above the inspection table 616, and then the Z stage embedded in the holding device 650 is driven to set the electronic component 1 on the inspection table 616. Since the posture of the electronic component 1 is adjusted using the fine adjustment mechanism in the holding device 650, it is possible to set the electronic component 1 at a correct position of the inspection table 616. After the electrical characteristics of the electronic component 1 are inspected using the inspection table 616, the electronic component 1 is picked up from the inspection table 616, the Y stage 632 and the X stage 636 are driven to move the holding device 650 to above the downstream-side stage 612d, and the electronic component 1 is placed on the downstream-side stage 612d. Thereafter, the downstream-side stage 612d is driven to convey the inspected electronic component 1 to a predetermined position.

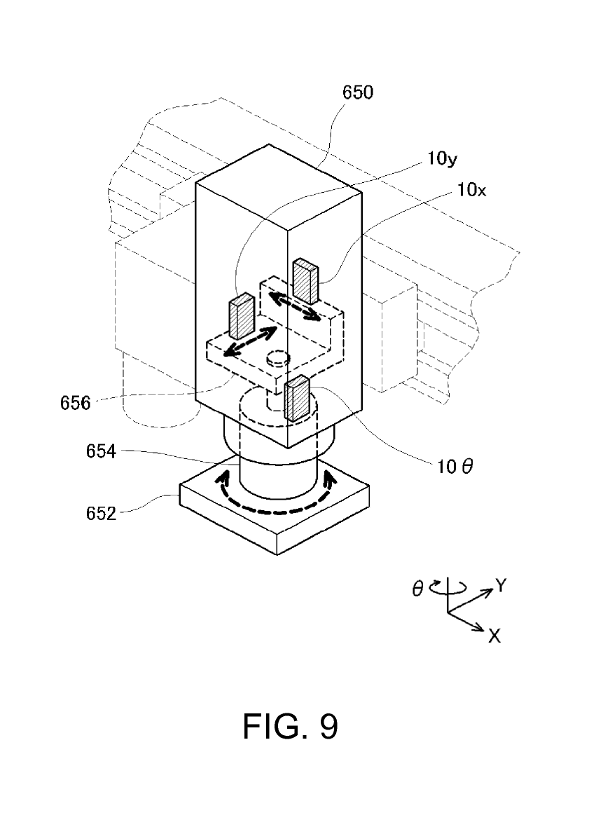

FIG. 9 is an explanatory view of the fine adjustment mechanism embedded in the holding device 650. As shown in the drawing, in the holding device 650 are provided a rotation shaft 654 connected to the holding portion 652, and a fine adjustment plate 656 to which the rotation shaft 654 is rotatably attached. The fine adjustment plate 656 is movable in the X direction and the Y direction using a guide mechanism (not shown).

As indicated by hatching in FIG. 9, a piezoelectric motor 10θ for a rotation direction toward the end surface of the rotation shaft 654 is mounted, and the driving convex portion (not shown) of the piezoelectric motor 10θ is pressed against the end surface of the rotation shaft 654. For this reason, if the piezoelectric motor 10θ is operated, it becomes possible to rotate the rotation shaft 654 (and the holding portion 652) in a θ direction by an arbitrary angle with high precision. A piezoelectric motor 10x for the X direction toward the fine adjustment plate 656 and a piezoelectric motor 10y for the Y direction are provided, and the driving convex portions (not shown) of the piezoelectric motors 10x and 10y are pressed against the surface of the fine adjustment plate 656. For this reason, if the piezoelectric motor 10x is operated, it becomes possible to move the fine adjustment plate 656 (and the holding portion 652) in the X direction by an arbitrary distance with high precision. Similarly, if the piezoelectric motor 10y is operated, it becomes possible to move the fine adjustment plate 656 (and the holding portion 652) in the Y direction by an arbitrary distance with high precision. Accordingly, in the electronic component inspection device 600 of FIG. 8, if the piezoelectric motor 10θ, the piezoelectric motor 10x, and the piezoelectric motor 10y are operated, it is possible to finely adjust the posture of the electronic component 1 held by the holding portion 652. In this example, the piezoelectric motor 10x and the piezoelectric motor 10y respectively correspond to the “first piezoelectric motor” and “second piezoelectric motor” according to the invention, and the piezoelectric motor 10θ corresponds to the “third piezoelectric motor” according to the invention. The rotation shaft 654 or the fine adjustment mechanism having the fine adjustment plate 656, the piezoelectric motor 10θ, the piezoelectric motor 10x, and the piezoelectric motor 10y corresponds to the “driving device” according to the invention.

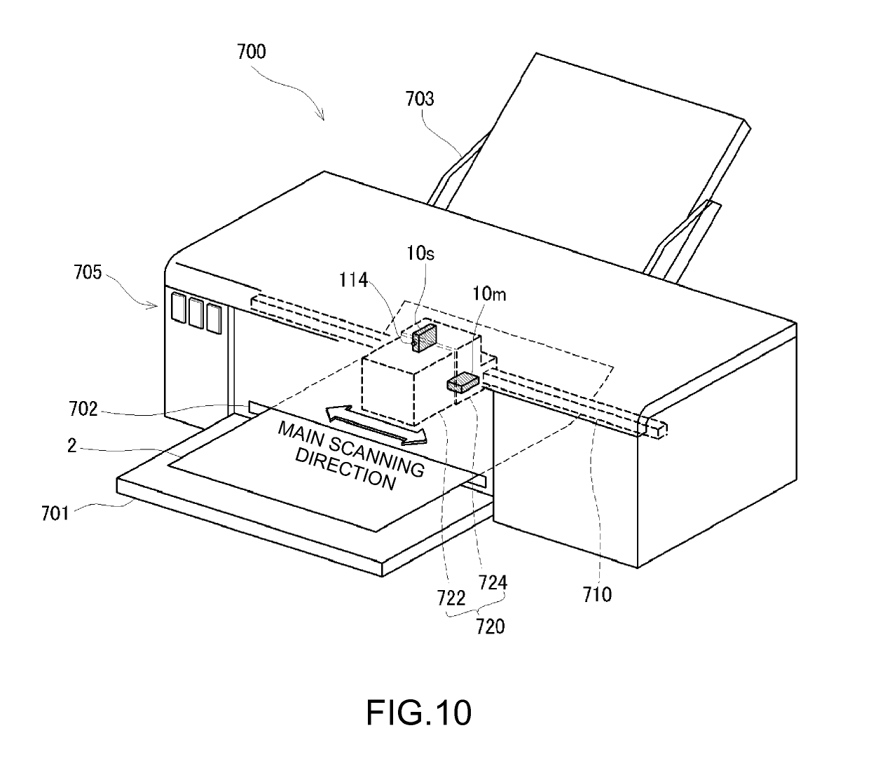

FIG. 10 is a perspective view illustrating a printing device 700 in which the piezoelectric motor 10 of this example is incorporated. The printing device 700 is a so-called ink jet printer which ejects ink onto the surface of a printing medium 2 to print an image. The printing device 700 substantially has a boxlike appearance shape, and is provided with a sheet discharge tray 701 substantially at the center of the front surface, a discharge port 702, and a plurality of operation buttons 705. A feed tray 703 is provided on the rear surface side. If the printing medium 2 is set in the feed tray 703 and the operation button 705 is operated, the printing medium 2 is drawn from the feed tray 703, an image is printed on the printing medium 2 inside the printing device 700, and the printing medium 2 is discharged from the discharge port 702.

Inside the printing device 700 are provided a carriage 720 which reciprocates in a main scanning direction on the printing medium 2, and a guide rail 710 which guides the movement of the carriage 720 in the main scanning direction. The carriage 720 has an ejection head 722 which ejects ink onto the printing medium 2, a driving unit 724 which drives the carriage 720 in the main scanning direction, and the like. A plurality of ejection nozzles are provided on the bottom surface side (the side toward the printing medium 2) of the ejection head 722, such that ink can be ejected from the ejection nozzles toward the printing medium 2. Piezoelectric motors 10m and 10s are mounted in the driving unit 724. The driving convex portion (not shown) of the piezoelectric motor 10m is pressed against the guide rail 710. For this reason, if the piezoelectric motor 10m is operated, it is possible to move the carriage 720 in the main scanning direction. The driving convex portion 114 of the piezoelectric motor 10s is pressed with respect to the ejection head 722. For this reason, if the piezoelectric motor 10s is operated, the bottom surface side of the ejection head 722 can be close to the printing medium 2 or can be away from the printing medium 2. In the printing device 700 which uses so-called roll paper as the printing medium 2, a mechanism for cutting roll paper with the image printed thereon is required. In this case, if a cutter is attached to the carriage 720 and moved in the main scanning direction, it is possible to cut roll paper.

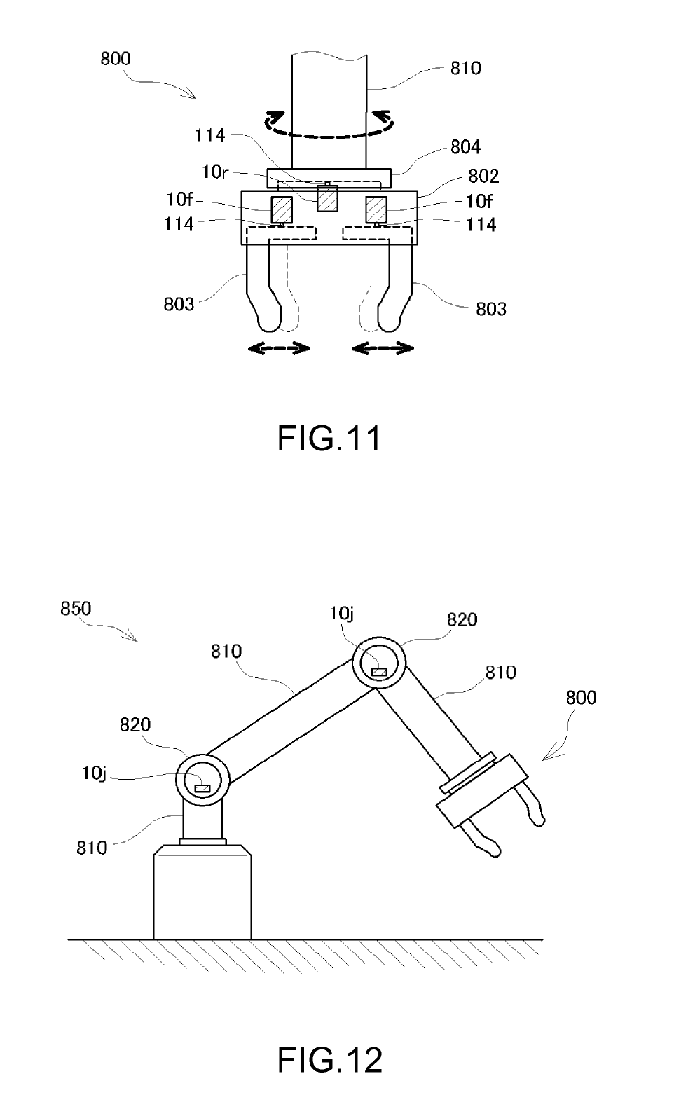

FIG. 11 is an explanatory view illustrating a robot hand 800 in which the piezoelectric motor 10 of this example is incorporated. In the robot hand 800, a plurality of finger portions 803 are provided upright from a base 802, and are connected to an arm 810 through a wrist 804. A root portion of each finger portion 803 is movable in the base 802, and a piezoelectric motor 10f is mounted in a state where a driving convex portion 114 is pressed against the root portion of the finger portion 803. For this reason, if the piezoelectric motors 10f are operated, the finger portions 803 can be moved to hold the object. A piezoelectric motor 10r is mounted in the portion of the wrist 804 in a state where a driving convex portion 114 is pressed against the end surface of the wrist 804. For this reason, if the piezoelectric motor 10r is operated, it is possible to rotate the entire base 802.

FIG. 12 is an explanatory view illustrating a robot 850 including the robot hand 800. As shown in the drawing, the robot 850 includes a plurality of arms 810, and joint portions 820 which connect the arms 810 in a bendable state. The robot hand 800 is connected to the tip of the arm 810. Each joint portion 820 is embedded with a piezoelectric motor 10j as an actuator for bending the joint portion 820. For this reason, if the piezoelectric motor 10j is operated, it is possible to bend each joint portion 820 by an arbitrary angle.

Although the piezoelectric motor according to the embodiment of the invention or various devices having the piezoelectric motor mounted therein have been described, the invention is not limited to the foregoing examples, modifications, and application examples, and may be carried out in various forms without departing from the scope of the invention.

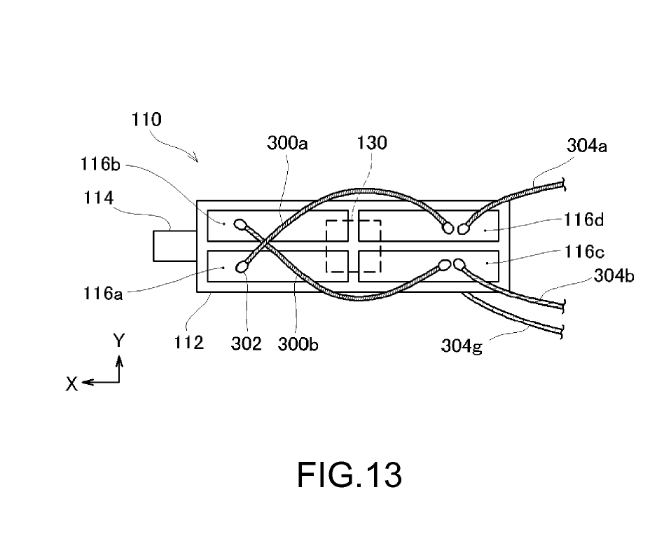

For example, in the above-described example, the vibrating body 112 is sandwiched by the support members 130 in the front node portion 118a and the rear node portion 118c from among the three node portions 118 of the vibrating body 112, and the wiring to the front electrodes 116 and the wiring to the rear electrode 115 are made in the center node portion 118b (see FIGS. 5 and 6). Meanwhile, it should suffice that the vibrating body 112 is sandwiched by the support members 130 in some node portions 118 from among the three node portions 118 and the wiring to the electrodes is made in any node portion 118 which is not sandwiched by the support members 130, and the invention is not limited to the form in the above-described example. For example, as shown in FIG. 13, the vibrating body 112 may be sandwiched by the support members 130 in the center node portion 118b, and the wiring to the front electrodes 116 (the bonding of the inter-electrode electric wires 300a and 300b and the external electric wires 304a and 304b by the solders 302) and the wiring to the rear electrode 115 (the bonding of the ground electric wire 306 by the solder 302) may be made in the front node portion 118a and the rear node portion 118c. In this case, as in the above-described example, it is possible to increase the amount of movement of the driving convex portion 114 of the vibrating body 112 or to suppress deviation of the wiring from the electrodes due to the bending vibration of the vibrating body 112 without increasing the amount of deformation of the support members 130. The vibrating body 112 may be sandwiched in either the front node portion 118a or the rear node portion 118c, and the wiring to the front electrodes 116 and the wiring to the rear electrode 115 may be made in the center node portion 118b.

The entire disclosure of Japanese Patent Application No. 2011-266552, filed Dec. 6, 2011 is expressly incorporated by reference herein.

What is claimed is:

1. A piezoelectric motor comprising:
a piezoelectric element;
an electrode which is arranged on one surface of the piezoelectric element, and applies a voltage to the piezoelectric element;
an electric wire which applies the voltage to the electrode;
a bond portion which electrically bonds the electrode and the electric wire;
a storage case which stores the piezoelectric element;
a support portion which is provided between the piezoelectric element and the storage case, and supports one surface,
wherein the bond portion is provided in the gap between the electrode and the storage case,
the height of the bond portion from the electrode and the outer diameter of the electric wire are smaller than the thickness of the support portion, and
one surface includes a direction in which the piezoelectric element undergoes bending vibration.

2. The piezoelectric motor according to claim 1,
wherein the vibrating body has
a plurality of antinode portions in which the amplitude of the bending vibration is the same as the end portion provided with the convex portion, and
a plurality of node portions in which the amplitude of the bending vibration is smaller than the antinode portions,
the support portions are in contact with the vibrating body in some node portions of the plurality of node portions, and
the bond portions are bonded to the electrodes in any node portion with which the support portions are not in contact.

3. The piezoelectric motor according to claim 1,
wherein the inner surface of the storage case facing the electrodes is coated with a non-conductive material.

4. The piezoelectric motor according to claim 1,
wherein the electrodes have
a first region and a second region which are connected together through a connection portion, and are formed as a single body including the connection portion, and
a third region and a fourth region which are formed to be electrically isolated from the first region and the second region, and are arranged on different sides with respect to the connection portion, and
the third region and the fourth region are connected together by the electric wires intersecting the connection portion.

5. A driving device comprising:
the piezoelectric motor according to claim 1.

6. A driving device comprising:
the piezoelectric motor according to claim 2.

7. A printing device comprising:
the piezoelectric motor according to claim 1.

8. A robot hand comprising:
the piezoelectric motor according to claim 1.

9. A robot comprising:
the piezoelectric motor according to claim 1.

10. A robot comprising:
the robot hand according to claim 8.

11. An electronic component inspection device which mounts a held electronic component in an inspection socket, and inspects the electrical characteristics of the electronic component,
wherein the electronic component is aligned with respect to the inspection socket by means of the piezoelectric motor according to claim 1.

12. An electronic component inspection device which mounts a held electronic component in an inspection socket, and inspects the electrical characteristics of the electronic component, the electronic component inspection device comprising:
a piezoelectric motor which aligns the electronic component with respect to the inspection socket,
wherein the piezoelectric motor includes
a vibrating body which is formed to contain a piezoelectric material, and if a voltage is applied, undergoes bending vibration,
a convex portion which is provided in an end portion of the vibrating body,
electrodes which are formed on both surfaces of the vibrating body facing in a direction intersecting a bending direction in which the end portion provided with the convex portion moves with bending vibration of the vibrating body, and to which the voltage is applied,
electric wires which are coated with a non-conductive material, and apply the voltage to the electrodes,
bond portions which electrically bond the electrodes and the electric wires,
a storage case which stores the vibrating body, and
support portions which are provided between the vibrating body and the storage case, and sandwich both surfaces of the vibrating body provided with the electrodes from the direction intersecting the bending direction of the vibrating body,
the bond portions are provided in the gap corresponding to the thickness of the support portions between the electrodes of the vibrating body and the storage case, and
the height of the bond portions from the electrodes and the outer diameter of the electric wires are smaller than the thickness of the support portions

13. An electronic component inspection device comprising:
an inspection socket in which an electronic component is mounted, and the electrical characteristics of the electronic component are inspected;
a holding device which holds an electronic component;
a moving device which moves the holding device in the direction of three axes in total of a first axis and a second axis perpendicular to each other and a third axis perpendicular to the first axis and the second axis;
an imaging device which is provided on the first axis or the second axis when viewed from the inspection socket, and detects a position in the directions of the first axis and the second axis and an angle around the third axis for the electronic component mounted in the inspection socket as the posture of the electronic component;
an upstream-side stage which conveys the electronic component from the inspection socket to a predetermined position on the first axis or the second axis connecting the imaging device;
a downstream-side stage which conveys the electronic component from a predetermined position opposite to the side on which the imaging device is provided when viewed from the inspection socket; and
a control device which controls the operation of the moving device,
wherein the control device includes
a first control unit which moves the holding device holding the electronic component conveyed by the upstream-side stage onto the imaging device,
a second control unit which moves the holding device to mount the electronic component whose posture is confirmed by the imaging device in the inspection socket, and
a third control unit which moves the holding device to place the electronic component whose electrical characteristics are inspected in the inspection socket from the inspection socket to the downstream-side stage,
the holding device has a first piezoelectric motor which moves the electronic component in the direction of the first axis on the basis of the posture of the electronic component detected by the imaging device, a second piezoelectric motor which moves the electronic component in the direction of the second axis on the basis of the posture of the electronic component detected by the imaging device, and a third piezoelectric motor which rotates the electronic component around the third axis on the basis of the posture of the electronic component detected by the imaging device, and
the first to third piezoelectric motors are the piezoelectric motor according to claim 1.

14. An electronic component conveying device which conveys a held electronic component,
wherein the electronic component is aligned by means of the piezoelectric motor according to claim 1.

15. An electronic component conveying device which conveys a held electronic component, the electronic component conveying device comprising:
a piezoelectric motor which aligns the electronic component,
wherein the piezoelectric motor includes
a vibrating body which is formed to contain a piezoelectric material, and if a voltage is applied, undergoes bending vibration,
a convex portion which is provided in an end portion of the vibrating body,
electrodes which are formed on both surfaces of the vibrating body facing in a direction intersecting a bending direction in which the end portion provided with the convex portion moves with bending vibration of the vibrating body, and to which the voltage is applied,
electric wires which are coated with a non-conductive material, and apply the voltage to the electrodes,
bond portions which electrically bond the electrodes and the electric wires,
a storage case which stores the vibrating body, and
support portions which are provided between the vibrating body and the storage case, and sandwich both surfaces of the vibrating body provided with the electrodes from the direction intersecting the bending direction of the vibrating body,
the bond portions are provided in the gap corresponding to the thickness of the support portions between the electrodes of the vibrating body and the storage case, and
the height of the bond portions from the electrodes and the outer diameter of the electric wires are smaller than the thickness of the support portions

16. An electronic component conveying device comprising:
a holding device which holds an electronic component;
a moving device which moves the holding device in the directions of three axes in total of a first axis and a second axis perpendicular to each other and a third axis perpendicular to the first axis and the second axis; and
a control device which controls the operation of the moving device,
wherein the holding device has a first piezoelectric motor which moves the electronic component in the direction of the first axis, a second piezoelectric motor which moves the electronic component in the direction of the second axis, and a third piezoelectric motor which rotates the electronic component around the third axis, and
the first to third piezoelectric motors are the piezoelectric motor according to claim 1.
